(19) United States
(12) Patent Application Publication
(10) Pub. No.: US 2026/0143992 A1
(43) Pub. Date: May 21, 2026

(54) SUBSTRATE PROCESSING APPARATUS

(71) Applicant: SEMES CO., LTD., Chungcheongnam-do (KR)

(72) Inventors: Jeong Bo SHIM, Suwon-si (KR); Won Sik SON, Hwaseong-si (KR); In Ki JUNG, Seongnam-si (KR); Jeong Hyup YU, Hwaseong-si (KR)

(21) Appl. No.: 19/366,639

(22) Filed: Oct. 23, 2025

(30) Foreign Application Priority Data
Oct. 28, 2024 (KR) 10-2024-0148617

(51) Int. Cl. H10P 72/00; H10P 70/00

(52) U.S. Cl. CPC H10P 72/0414; H10P 70/15; H10P 72/0408

(57) ABSTRACT

Provided is an apparatus for processing a substrate. The apparatus includes a cleaning unit for cleaning a nozzle. The cleaning unit includes: a body having an inner space; a first inner plate for dividing the inner space into a first space and a first buffer space; a cleaning liquid supply pipe for supplying a cleaning liquid to clean the nozzle into the first buffer space; a first driver for rotating the first inner plate; a second inner plate for dividing the inner space into a second space and a second buffer space; a second gas supply pipe for supplying gas to dry the nozzle into the second buffer space; and a second driver for rotating the second inner plate.

### CROSS-REFERENCE TO RELATED APPLICATION

This application claims priority to and the benefit of Korean Patent Application No. 10-2024-0148617 filed in the Korean Intellectual Property Office on Oct. 28, 2024, the entire contents of which are incorporated herein by reference.

### TECHNICAL FIELD

The present invention relates to a substrate processing apparatus, and more particularly, to a substrate processing apparatus including a cleaning unit for cleaning a nozzle that discharges a treatment liquid to a substrate.

### BACKGROUND ART

To manufacture a semiconductor device or liquid crystal display, various processes, such as photolithography, etching, ashing, ion implantation, thin film deposition, and cleaning, are performed on a substrate. Among them, the cleaning process is a process of removing particles on the substrate by supplying a treatment liquid, such as chemical, organic solvent, or water, onto the substrate. A typical device for performing a cleaning process has a spin chuck supporting a substrate in a treatment space provided in a cup and a nozzle for supplying a treatment liquid onto the substrate. As for the nozzle used in the cleaning process, a treatment liquid of various components is used, so a separate nozzle is used according to each treatment liquid. When chemical, organic solvent, or water is used as the treatment liquid, three nozzles may be provided. When the cleaning of the substrate is not performed, the nozzle waits in a cleaning unit located on one side of the cup.

When the treatment liquid is supplied onto the substrate, the treatment liquid is bounced back to the nozzle and contaminates the nozzle. The treatment liquid solidified at the end of the nozzle acts as particles when processing the subsequent substrate, contaminating the subsequent substrate. Thus, while the nozzle waits in the cleaning unit, the outer surface of the nozzle is cleaned.

FIG. 1 is a plan view schematically illustrating a structure of a general cleaning unit.

Referring to FIG. 1, a plurality of nozzles 490 that have processed the substrate is inserted into a cleaning unit 501. When the nozzle is inserted into the cleaning unit, a cleaning liquid is supplied from the cleaning nozzle 502 toward an end or an outer surface of the nozzle. However, as the plurality of nozzles 490 is inserted, there is a region A that cannot be cleaned by the cleaning liquid in the space between the respective nozzles 490. In addition, when the nozzles 490 are not arranged in a row, the uncleaned region A formed between the respective nozzles 490 in the central region further increases. As a result, cleaning efficiency is greatly reduced.

In addition, as a number of cleaning nozzles is installed, the structure within the cleaning unit becomes complicated, and the number of components provided to the cleaning unit increases.

### SUMMARY OF THE INVENTION

The present invention has been made in an effort to provide a substrate processing apparatus capable of improving the cleaning efficiency of a nozzle used for substrate processing.

The present invention has also been made in an effort to provide a substrate processing apparatus capable of preventing significant decreases in cleaning efficiency of some nozzles when cleaning multiple nozzles in a standby port.

The present invention has also been made in an effort to provide a substrate processing apparatus capable of improving the cleaning efficiency of regions where nozzles face each other when cleaning multiple nozzles in a cleaning unit.

The objectives of the present disclosure are not limited thereto and other objectives not stated herein may be clearly understood by those skilled in the art from the following description.

An exemplary embodiment of the present disclosure, an apparatus for processing a substrate, the apparatus may comprising: a cup unit having a treatment space for liquid-treating a substrate with a treatment liquid; a support unit for supporting the substrate within the treatment space; a nozzle unit including a nozzle that supplies a treatment liquid to the substrate supported by the support unit; and a cleaning unit located on one side of the cup unit and cleaning the nozzle, wherein the cleaning unit includes: a body having an inner space; a first inner plate for dividing the inner space into a first space where the nozzle is located and a first buffer space outside the first space; a cleaning liquid supply pipe with a liquid valve installed and supplying a cleaning liquid for cleaning the nozzle located in the first space into the first buffer space; a first driver for rotating the first inner plate about a central axis thereof; a second inner plate for dividing the inner space into a second space at a height different from the first space and a second buffer space outside the second space; a second gas supply pipe with a second gas valve installed and supplying gas for drying the nozzle located in the second space into the second buffer space; and a second driver for rotating the second inner plate about a central axis thereof.

According to the exemplary embodiment of the present invention, wherein a plurality of through holes may be formed in the first inner plate to allow a fluid to flow between the first buffer space and the first space.

According to the exemplary embodiment of the present invention, the apparatus may further include a controller for controlling the first driver, wherein the controller may controls the first driver to increase the number of rotations of the first inner plate as more contaminants generated due to the treatment liquid used for substrate processing remaining on a nozzle tip are attached.

According to the exemplary embodiment of the present invention, wherein the contaminant may be a salt compound.

According to the exemplary embodiment of the present invention, wherein the nozzle unit further includes: a support frame; a plurality of arms supported side by side on the support frame in one direction, with the nozzles respectively installed at their ends; and a nozzle driver for driving the support frame so that the nozzle is moved between a standby position and a process position, the apparatus further includes a controller for controlling the first driver, the second driver, the liquid valve, the second gas valve, the first depressurization member, and the nozzle driver, and the controller controls the second driver, the liquid valve, the second gas valve, the first depressurization member, and the nozzle driver to perform: a second drying operation of drying the nozzle with gas supplied through the second buffer space by closing the liquid valve and opening the second gas valve while rotating the second inner plate, after the nozzle located in the first space is inserted into the second space; and a first exhaust operation of exhausting the gas in the inner space to the outside through the first depressurization member while the second drying operation may be performed.

According to the exemplary embodiment of the present invention, wherein in the first cleaning operation, the first inner plate is rotated in a first direction, and the controller may controls the first driver to perform a second cleaning operation of cleaning the nozzle with the cleaning liquid supplied through the first buffer space while rotating the first inner plate in a second direction opposite to the first direction, after the first cleaning operation.

According to the exemplary embodiment of the present invention, wherein the nozzle unit further includes: a support frame; a plurality of arms supported side by side on the support frame in one direction, with the nozzles respectively installed at their ends; and a nozzle driver for driving the support frame so that the nozzle is moved between the first space and the second space, the nozzles installed in the plurality of arms are simultaneously inserted from the first space to the second space, the controller further controls the second driver, the second gas valve, and the nozzle driver, and the controller may controls the second driver, the second gas valve, and the nozzle driver to perform a first drying operation of drying the nozzle with gas supplied through the second buffer space by closing the liquid valve and opening the second gas valve while rotating the second inner plate after the nozzle located in the first space is inserted into the second space.

According to the exemplary embodiment of the present invention, wherein in the first drying operation, the second inner plate rotates in the first direction, and the controller controls the second driver to perform a second drying operation of drying the nozzle with the gas supplied through the second buffer space while rotating the second inner plate in a second direction opposite to the first direction after the first drying operation, and the first drying operation and the second drying operation are repeatedly may performed several times.

According to the exemplary embodiment of the present invention, wherein the cleaning unit further includes a first gas supply pipe in which a first gas valve is installed and which supplies gas for drying the nozzle located in the first space into the first buffer space, and a second depressurization member for exhausting the gas in the inner space to the outside is further may installed in the second gas supply pipe.

According to the exemplary embodiment of the present invention, wherein the nozzle unit further includes: a support frame; a plurality of arms supported side by side on the support frame in one direction, with the nozzles respectively installed at their ends; and a nozzle driver for driving the support frame so that the nozzle is moved between a standby position and a process position, the apparatus further includes a controller for controlling the first driver, the second driver, the liquid valve, the first gas valve, the first depressurization member, and the nozzle driver, and the controller controls the first driver, the liquid valve, the first gas valve, the first depressurization member, and the nozzle driver to perform: a first cleaning operation of cleaning the nozzle with a cleaning liquid supplied through the first buffer space by opening the liquid valve while rotating the first inner plate after the nozzle located in the standby position is inserted into the first space; a first drying operation of drying the nozzle with the gas supplied through the first buffer space by opening the first gas valve while rotating the first inner plate after the first cleaning operation is performed; and an exhaust operation of exhausting the gas in the inner space to the outside through the second depressurization member while the first drying operation may be performed.

According to the exemplary embodiment of the present invention, wherein the cleaning unit further includes a second gas supply pipe in which a second gas valve is installed and which supplies gas for drying the nozzle located in the second space into the second buffer space, and a first depressurization member for exhausting the gas in the inner space to the outside may be further installed in the first gas supply pipe.

According to the exemplary embodiment of the present invention, wherein the nozzle unit further includes: a support frame; a plurality of arms supported side by side on the support frame in one direction, with the nozzles respectively installed at their ends; and a nozzle driver for driving the support frame so that the nozzle is moved between a standby position and a process position, and the nozzle installed in the plurality of arms is inserted into the inner space from the standby position by the nozzle driver, the apparatus further includes a controller for controlling the first driver, the liquid valve, the first gas valve, and the nozzle driver, and the controller controls the first driver, the liquid valve, and the nozzle driver to perform a first cleaning operation of cleaning the nozzle with a cleaning liquid supplied through the first buffer space by opening the liquid valve while rotating the first inner plate after the nozzle located in the standby position may be inserted into the first space.

According to the exemplary embodiment of the present invention, wherein the cleaning unit further may includes: a third inner plate for dividing the inner space into a third space where the nozzle is located and a third buffer space outside the third space; a second cleaning liquid supply pipe with a second liquid valve installed and supplying a cleaning liquid to clean the nozzle located in the third space into the third buffer space; and a third driver for rotating the third inner plate about a central axis thereof.

An exemplary embodiment of the present disclosure, an apparatus for processing a substrate, the apparatus comprising: a cup unit having a treatment space for liquid-treating a substrate with a treatment liquid; a support unit for supporting the substrate within the treatment space; a nozzle unit including a nozzle that supplies a treatment liquid to the substrate supported by the support unit; and a cleaning unit located on one side of the cup unit and cleaning the nozzle, wherein the cleaning unit includes: a body having an inner space; a first inner plate for dividing the inner space into a first space where the nozzle is located and a first buffer space outside the first space; a cleaning liquid supply pipe with a liquid valve installed and supplying a cleaning liquid for cleaning the nozzle located in the first space into the first buffer space; a first gas supply pipe with a first gas valve installed and supplying gas for drying the nozzle located in the first space into the first buffer space; and a first driver for rotating the first inner plate about a central axis thereof, and a plurality of through holes are formed in the first inner plate to allow a fluid to flow between the first buffer space and the first space.

According to the exemplary embodiment of the present invention, wherein the nozzle unit further includes: a support frame; a plurality of arms supported side by side on the support frame in one direction and equipped with the nozzles at ends, respectively; and a nozzle driver for driving the support frame so that the nozzle is moved between a standby position and a process position, the nozzle installed in the plurality of arms is inserted into the inner space from the standby position by the nozzle driver, the apparatus further comprises a controller for controlling the first driver, the liquid valve, and the nozzle driver, and the controller may controls the first driver, the liquid valve, and the nozzle driver to perform a first cleaning operation of cleaning the nozzle with a cleaning liquid supplied through the first buffer space by opening the liquid valve while rotating the first inner plate after the nozzle located in the standby position is inserted into the first space.

According to the exemplary embodiment of the present invention, wherein in the first cleaning operation, the first inner plate is rotated in a first direction, and the controller may controls the first driver to perform a second cleaning operation of cleaning the nozzle with the cleaning liquid supplied through the first buffer space while rotating the first inner plate in a second direction opposite to the first direction, after the first cleaning operation.

According to the exemplary embodiment of the present invention, a controller for controlling the first driver, wherein the controller may controls the first driver to increase the number of rotations of the first inner plate as more contaminants generated due to the treatment liquid used for substrate processing remaining on a nozzle tip are attached.

According to the exemplary embodiment of the present invention, wherein the contaminant may be a salt compound.

According to the exemplary embodiment of the present invention, wherein a first depressurization member for exhausting the gas in the inner space to the outside is further installed in the cleaning liquid supply pipe, the apparatus further includes a controller for controlling the first driver, the liquid valve, the first gas valve, the first depressurization member, and the nozzle driver, and the controller controls the first driver, the liquid valve, the first gas valve, and the first depressurization member to perform an exhaust operation of exhausting the gas in the inner space to the outside through the first depressurization member while a first drying operation of drying the nozzle with gas supplied through the first buffer space is performed by closing the liquid valve and opening the first gas valve while rotating the first inner plate, after the first cleaning operation may be performed.

An exemplary embodiment of the present disclosure, an apparatus for processing a substrate, the apparatus comprising: a cup unit having a treatment space for liquid-treating a substrate with a treatment liquid; a support unit for supporting the substrate within the treatment space; a nozzle unit including a nozzle that supplies a treatment liquid to the substrate supported by the support unit; and a cleaning unit located on one side of the cup unit and cleaning the nozzle, wherein the cleaning unit includes: a support frame; a plurality of arms supported side by side on the support frame in one direction, with the nozzles respectively installed at their ends; a nozzle driver for driving the support frame so that the nozzle is moved between a standby position and a process position; a body having an inner space; a first inner plate for dividing the inner space into a first space where the nozzle is located and a first buffer space outside the first space; a cleaning liquid supply pipe with a liquid valve installed and supplying a cleaning liquid for cleaning the nozzle located in the first space into the first buffer space; a first driver for rotating the first inner plate about a central axis thereof; a second inner plate for dividing the inner space into a second space at a height different from the first space and a second buffer space outside the second space; a second gas supply pipe with a second gas valve installed and supplying gas for drying the nozzle located in the second space into the second buffer space; and a second driver for rotating the second inner plate about a central axis thereof, and a plurality of through holes are formed in the first inner plate to allow a fluid to flow between the first buffer space and the first space, a plurality of through holes are formed in the second inner plate to allow a fluid to flow between the second buffer space and the second space, the nozzle installed in the plurality of arms is inserted into the inner space from the standby position by the nozzle driver, the apparatus further includes a controller for controlling the first driver, the liquid valve, the second gas valve, and the nozzle driver, and the controller controls the first driver, the second driver, the liquid valve, the second gas valve, and the nozzle driver to perform: a first cleaning operation of cleaning the nozzle with a cleaning liquid supplied through the first buffer space by opening the liquid valve while rotating the first inner plate in a first direction, after the nozzle located in the standby position is inserted into the first space; a second cleaning operation of cleaning the nozzle with the cleaning liquid supplied through the first buffer space while rotating the first inner plate in a second direction opposite to the first direction, after the first cleaning operation; and a second drying operation of drying the nozzle with gas supplied through the second buffer space by closing the liquid valve and opening the second gas valve while rotating the second inner plate, after the nozzle located in the first space may be inserted into the second space.

According to the exemplary embodiment of the present invention, it is possible to improve the cleaning efficiency of a nozzle used for substrate processing.

Further, according to the exemplary embodiment of the present invention, it is possible to prevent significant decreases in cleaning efficiency of some nozzles when cleaning multiple nozzles in a cleaning unit.

Further, according to the exemplary embodiment of the present invention, it is possible to improve the cleaning efficiency of regions where nozzles face each other when cleaning multiple nozzles in a cleaning unit.

Effects of the present disclosure are not limited to those described above and effects not stated above will be clearly understood to those skilled in the art from the specification and the accompanying drawings.

### BRIEF DESCRIPTION OF THE DRAWINGS

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

FIG. 1 is a plan view schematically illustrating a structure of a general cleaning unit.

FIG. 2 is a plan view schematically illustrating a substrate processing apparatus according to an exemplary embodiment of the present invention.

FIG. 3 is a diagram schematically illustrating an exemplary embodiment of a liquid treating chamber of FIG. 2.

FIG. 4 is a diagram schematically illustrating an exemplary embodiment of a nozzle unit of FIG. 3.

FIG. 5 is a cross-sectional view schematically illustrating an exemplary embodiment of a cleaning unit of FIG. 3.

FIG. 6 is a flowchart schematically illustrating a nozzle cleaning method according to an exemplary embodiment of the present invention.

FIG. 7 is a cross-sectional view schematically illustrating a position of a nozzle in a first moving operation of FIG. 6.

FIG. 8 is a cross-sectional view schematically illustrating the cleaning unit in a nozzle cleaning operation of FIG. 6.

FIG. 9 is a cross-sectional view schematically illustrating a position of a nozzle in a second moving operation of FIG. 6.

FIG. 10 is a cross-sectional view schematically illustrating the cleaning unit in a nozzle drying operation of FIG. 6.

FIG. 11 is a cross-sectional view schematically illustrating another example of the cleaning unit of FIG. 5.

FIG. 12 is a flowchart schematically illustrating a nozzle cleaning method according to FIG. 11.

FIGS. 13 to 16 are diagrams schematically illustrating another example of the cleaning unit of FIG. 5.

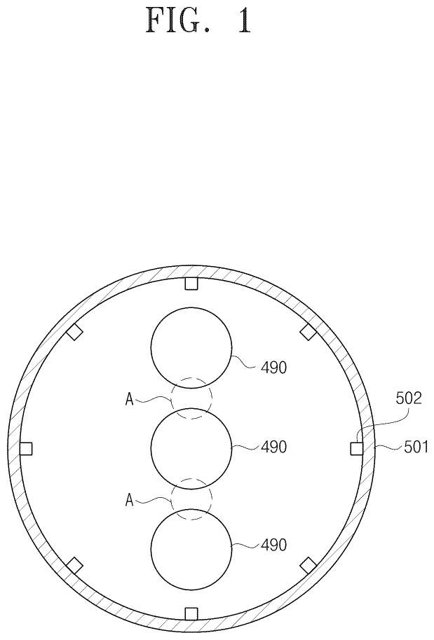

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.
Am expression, “and/or” includes each of the mentioned items and all of the combinations including one or more of the items. Further, in the present specification, “connected” means not only when member A and member B are directly connected, but also when member A and member B are indirectly connected by interposing member C between member A and member B.

Embodiments of the present disclosure may be modified in various ways and the scope of the present disclosure should not be construed as being limited to the embodiments to be described below. Embodiments are provided to more completely explain the present disclosure to those skilled in the art. Accordingly, the shapes of the components shown in the figures are exaggerated to enhance clearer description.

In the present invention, a wafer used for manufacturing a semiconductor is described as an example of a substrate W. However, unlike this, the substrate W may be a mask or a flat panel display panel.

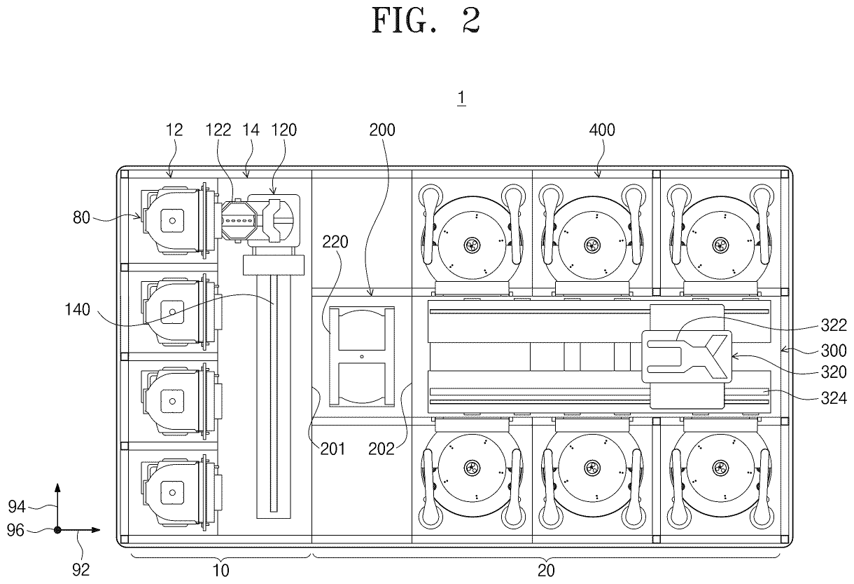

FIG. 2 is a plan view schematically illustrating a substrate processing apparatus according to an exemplary embodiment of the present invention.

Referring to FIG. 2, a substrate processing apparatus 1 includes an index module 10, a treating module 20, and a controller 2. The index module 10 and the treating module 20 are disposed along one direction. Hereinafter, the direction in which the index module 10 and the treating module 20 are disposed is referred to as a first direction 92, and when viewed from above, a direction perpendicular to the first direction 92 is referred to as a second direction 94, and a direction perpendicular to both the first direction 92 and the second direction 94 is referred to as a third direction 96.

The index module 10 transfers a substrate W from a container 80 in which the substrate W is accommodated to the treating module 20, and makes the substrate W, which has been completely processed in the treating module 20, be accommodated in the container 80. A longitudinal direction of the index module 10 is provided in the second direction 94. The index module 10 includes a load port 12 and an index frame 14. Based on the index frame 14, the load port 12 is located at a side opposite to the treating module 20. The containers 80 in which the substrates W are accommodated are placed on the load ports 12. The load port 12 may be provided in plural, and the plurality of load ports 12 may be disposed in the second direction 94.

An index robot 120 is provided to the index frame 14. A guide rail 140 of which a longitudinal direction is the second direction 94 is provided within the index frame 14, and the index robot 120 may be provided to be movable along the guide rail 140. The index robot 120 includes a hand 122 on which the substrate W is placed. The hand 122 may be provided to move forward and backward, rotate around the third direction 96, and be movable along the third direction 96. The plurality of hands 122 is provided while being spaced apart from each other in the up and down direction, and is capable of independently moving forward and backward.

The treating module 20 includes a buffer unit 200, a transfer chamber 300, and a liquid treating chamber 400.

The buffer unit 200 provides a space in which the substrate W moved between the index module 10 and the transfer chamber 300 temporarily stays. The liquid treating chamber 400 performs a liquid treatment process of liquid-treating the substrate W by supplying a liquid onto the substrate W. The transfer chamber 300 transfers the substrate W between the buffer unit 200 and the liquid treating chamber 400.

The transfer chamber 300 may be provided so that a longitudinal direction thereof is the first direction 92. The buffer unit 200 may be disposed between the index module 10 and the transfer chamber 300. A plurality of liquid treating chambers 400 is provided. The liquid treating chamber 400 may be disposed on a side portion of the transfer chamber 300. The liquid treating chamber 400 and the transfer chamber 300 may be disposed in the second direction 94. The buffer unit 200 may be located at one end of the transfer chamber 300.

According to the example, the liquid treating chambers 400 are respectively disposed on opposite sides of the transfer chamber 300. At each of opposite sides of the transfer chamber 300, the liquid treating chambers 400 may be provided in an array of A×B (each of A and B is 1 or a natural number greater than 1) in the first direction 92 and the third direction 96.

The transfer chamber 300 includes a transfer robot 320. A guide rail 340 whose longitudinal direction is provided in the first direction 92 is provided within the transfer chamber 300, and the transfer robot 320 may be provided to be movable on the guide rail 340. The transfer robot 320 includes a hand 322 on which the substrate W is placed. The hand 322 may be provided to move forward and backward, rotate around the third direction 96, and be movable along the third direction 96. The plurality of hands 322 is provided while being spaced apart from each other in the vertical direction, and is capable of independently moving forward and backward.

The buffer unit 200 includes a plurality of buffers 220 on which the substrate W is placed. The buffers 220 may be disposed while being spaced apart from each other in the third direction 96. A front face 201 and a rear face 202 of the buffer unit 200 are opened. The front face 201 of the buffer unit 200 is a face facing the index module 10, and the rear face 202 of the buffer unit 200 is a face facing the transfer chamber 300. The index robot 120 may approach the inside of the buffer unit 200 through the front face 201 of the buffer unit 200, and the transfer robot 320 may approach the buffer unit 200 through the rear face 202 of the buffer unit 200.

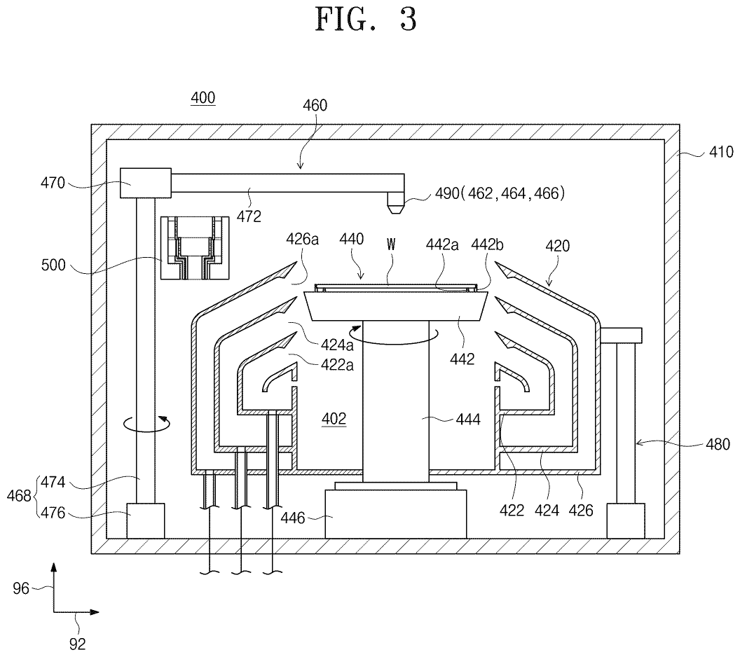

FIG. 3 is a diagram schematically illustrating an exemplary embodiment of a liquid treating chamber of FIG. 2.

Referring to FIG. 3, the liquid treating chamber 400 includes a housing 410, a cup 420, a support unit 440, a lifting unit 480, a nozzle unit 460, and a cleaning unit 500.

The housing 410 is provided in a generally rectangular parallelepiped shape. The cup 420, the support unit 440, the nozzle unit 460, the lifting unit 480, and the cleaning unit 500 are disposed within the housing 410.

The cup unit 420 has a treatment space 402 in which an upper portion is opened. The cup unit 420 includes an inner cup 422, an intermediate cup 424, and an outer cup 426. The inner cup 422, the intermediate cup 424, and the outer cup 426 each have recovery spaces for recovering a liquid used for processing the substrate W. The inner cup 422, the intermediate cup 424, and the outer cup 426 are each provided in a ring shape surrounding the support unit 440. When the liquid treatment process is performed, the treatment liquid scattered by rotation of the substrate W flows into the recovery spaces through the inlets 422a, 424a, and 426a of the inner cup 422, the intermediate cup 424, and the outer cup 426. According to the exemplary embodiment, the inner cup 422 is disposed to surround the support unit 440, the intermediate cup 424 is disposed to surround the inner cup 422, and the outer cup 426 is disposed to surround the intermediate cup 424. The intermediate cup inlet 424a through which the liquid flows into the intermediate cup 424 may be positioned above the inner cup inlet 422a through which the liquid flows into the inner cup 422, and the outer cup inlet 426a through which the liquid flows into the outer cup 426 may be positioned above the intermediate cup inlet 424a through which the liquid flows into the intermediate cup 424.

The support unit 440 supports the substrate W in the treatment space 402. The support unit 440 includes a spin chuck 442 and a drive shaft 444. An upper surface of the spin chuck 442 may be provided in a generally circular shape, and may have a diameter larger than a diameter of the substrate W. A chuck pin 442b is provided at an edge of the spin chuck 442. The chuck pin 442b is provided to protrude upward from the spin chuck 442. The chuck pin 442b supports a side portion of the substrate W so that the substrate W does not deviate from the support unit 440 when the substrate W is rotated. Also, a support pin 442a is provided to the spin chuck 442. The support pin 442a is provided with a top end protruding from the spin chuck 442 such that the substrate W is spaced a certain distance from the spin chuck 442. The support pin 442a is disposed closer to a center of the spin chuck 442 than the chuck pin 442b. The drive shaft 444 is driven by the driver 446, is connected to a center of a bottom surface of the substrate W, and rotates the spin chuck 442 with respect to its central axis.

The lifting unit 480 adjusts a relative height between the cup 420 and the support unit 440. According to an example, the lifting unit 480 moves the cup 420 in the up and down direction. By the up and down movement of the cup 420, a relative height between the cup 420 and the substrate W is changed. Accordingly, the recovery containers 422, 424, and 426 for recovering the treatment liquid are changed according to the type of liquid supplied to the substrate W, and thus the treatment liquids may be separated and recovered. Unlike the description, the cup 420 may be fixedly installed, and the lifting unit 480 may move the support unit 440 in the vertical direction.

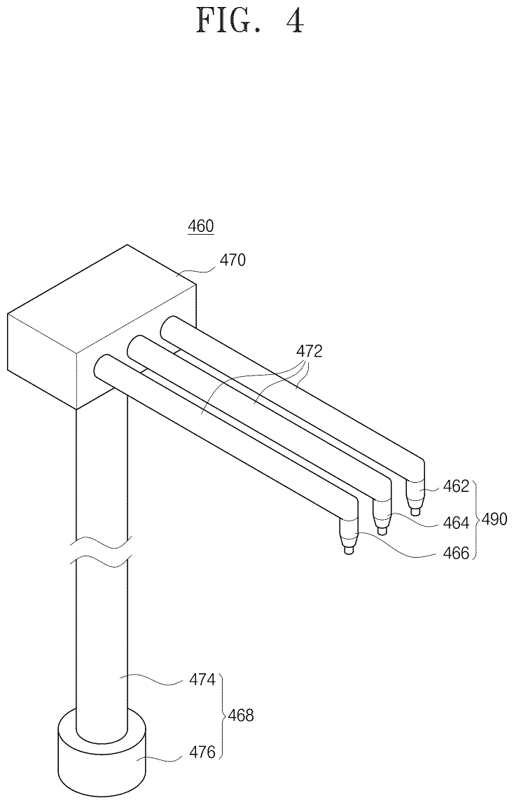

FIG. 4 is a diagram schematically illustrating an exemplary embodiment of a nozzle unit of FIG. 3.

Referring to FIG. 4, the nozzle unit 460 supplies a treatment liquid onto the substrate W supported on the support unit 440. The treatment liquid may be provided in a plurality of types, and may be sequentially supplied onto the substrate W. The nozzle unit 460 includes a support frame 470, an arm 472, a first nozzle 462, a second nozzle 464, a third nozzle 466, and a nozzle driver 468.

The first nozzle 462 supplies a first treatment liquid onto the substrate W. The second nozzle 464 supplies a second treatment liquid onto the substrate W. The third nozzle 466 supplies the third treatment liquid onto the substrate W. The first treatment liquid, the second treatment liquid, and the third treatment liquid are different types of treatment liquids. The first treatment liquid, the second treatment liquid, and the third treatment liquid may be an acidic component, an alkali component, or a neutral component. For example, the first treatment liquid, the second treatment liquid, and the third treatment liquid may be an acid component, such as sulfuric acid, hydrofluoric acid, phosphoric acid, or hydrochloric acid, or may be an alkali component, such as ammonia, or water.

Meanwhile, a nozzle unit 460 for supplying another type of treatment liquid may be further provided. For example, the nozzle unit 460 may further include a nozzle for supplying an organic solvent, such as isopropyl alcohol (IPA).

The support frame 470 supports the arm 472. A plurality of arms 472 is provided so that each nozzle 490 is installed. Each nozzle 490 is installed at an end of the arm 472. The arm 472 is provided side by side in one direction. The nozzle driver 468 has a drive shaft 474 and a driver 476. The nozzle driver 468 drives the support frame 470 such that the nozzles 490 move between a process position P and a standby position R. The process position P is a position at which the nozzle 490 supplies the treatment liquid onto the substrate W. The standby position R is a position at which the nozzle 490 which has completed supplying the treatment liquid onto the substrate W waits in the cleaning unit 500 until the next processing of the substrate W.

When viewed from the top, the nozzle 490 located at the standby position R overlaps the cleaning unit 500. The nozzle 490 is moved between the process position P and the standby position R by the nozzle driver 468. In addition, the nozzle 490 may be moved up and down in the third direction 96 by the nozzle driver 468. The standby position R is a position where a nozzle tip 494 is inserted into an inner space 528 of the cleaning unit 500. The nozzle 490 located at the standby position R may discharge the treatment liquid remaining in the nozzle 490 to the cleaning unit 500.

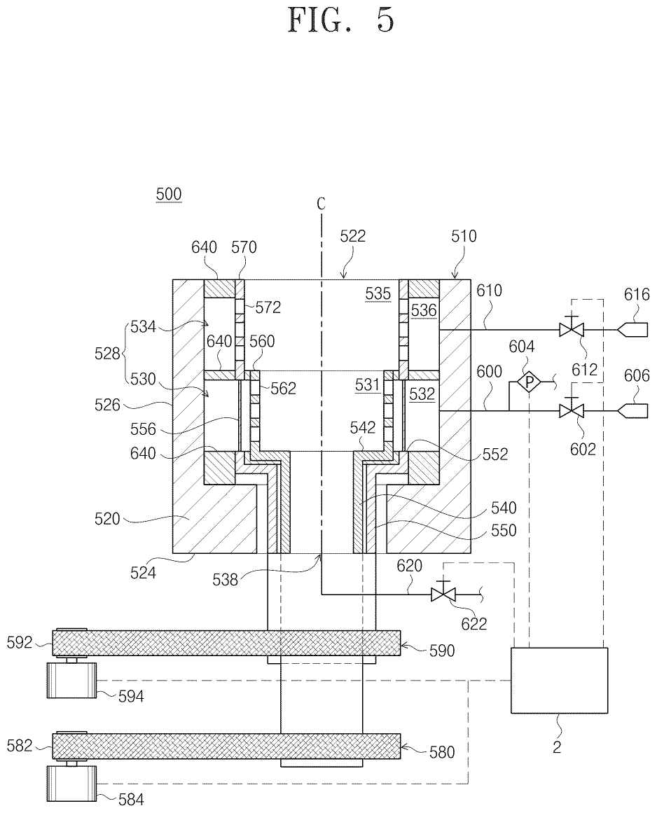

FIG. 5 is a cross-sectional view schematically illustrating an exemplary embodiment of the cleaning unit of FIG. 3.

Referring to FIG. 5, the cleaning unit 500 includes a body 510, a first inner plate 560, a second inner plate 570, a first driver 580, a second driver 590, a cleaning liquid supply pipe 600, a second gas supply pipe 610, and a liquid discharge pipe 620.

The body 510 has an outer wall 520, a first hollow shaft 540, and a second hollow shaft 550. An upper portion 522 of the outer wall 520 is open. The outer wall 520 is provided in a hollow cylindrical shape. The outer wall 520 is provided in a ring shape when viewed from the top. A bottom surface 524 of the outer wall 520 is provided as a flat surface. A discharge port 538 is formed at the center of the bottom surface 524 of the outer wall 520. A liquid discharge pipe 620 is connected to the discharge port 538. An opening/closing valve 622 is installed at the liquid discharge pipe 620. The treatment liquid discharged from the nozzle 490 and the cleaning liquid that has cleaned the nozzle 490 are discharged to the liquid discharge pipe 620 through the discharge port 538.

The outer wall 520 has an inner space 528 surrounded by a side surface 526 and the bottom surface 524. The inner space 528 is divided into a first region 530 and a second region 534 according to its height. The first region 530 includes a first space 531 and a first buffer space 532. The second region 534 includes a second space 535 and a second buffer space 536.

The first inner plate 560 is provided in the first region 530 of the inner space 528. The first inner plate 560 separates the first region 530 of the inner space 528 into the first space 531 and the first buffer space 532. In the first space 531, the nozzle 490 is cleaned by a cleaning liquid. The first buffer space 532 is located outside the first space 531. The first buffer space 532 is formed in a ring shape to surround the first space 531. The first inner plate 560 has a smaller diameter than the side surface 526 of the outer wall 520. A separation wall 640 is provided to an upper portion and a lower portion of the first buffer space 532 to separate the first buffer space 532 into the first buffer space 532 and the second buffer space 535. A bearing may be installed at a point where the separation wall 640 is in contact with the first inner plate 560.

A plurality of through holes 562 is formed in the first inner plate 560. A plurality of through holes 562 is formed to form a plurality of rows in a direction along the circumference of the side surface 526 of the outer wall 520. For example, a plurality of through holes 562 may be formed to form three rows in the first inner plate 560. A plurality of through holes 562 is formed in a horizontal direction with respect to the ground.

The second inner plate 570 is provided in the second region 534 of the inner space 528. The first region 530 and the second region 534 of the inner space 528 are regions having different heights. According to an example, the second region 534 is a region at a higher position than the first region 530. The second inner plate 570 separates the second region 534 into a second space 535 and a second buffer space 536. According to an example, the second space 535 is a space into which the nozzle 490 is inserted at a higher position than the first space 531. In this case, the upper portion 522 of the outer wall 520 is provided in an open structure. In the second space 535, the nozzle 490 is dried by gas. The second buffer space 536 is located outside the second space 535. The second buffer space 536 is formed in a ring shape surrounding the second space 535. The second buffer space 536 is located above the first buffer space 532. The second inner plate 570 has a smaller diameter than the side surface 526 of the outer wall 520. The second inner plate 570 has a larger diameter than the first inner plate 560 when viewed from above. The separation wall 640 separating the second buffer space 536 from the outside is provided at upper and lower portions of the second buffer space 536. A bearing may be installed at a point where the separation wall 640 is in contact with the second inner plate 570.

The plurality of through holes 572 are formed in the second inner plate 570. A plurality of through holes 572 is formed to form a plurality of rows in a direction along the circumference of the side surface 526 of the outer wall 520. For example, a plurality of through holes 572 may be formed to form three rows in the second inner plate 570.

The first hollow shaft 540 is provided in a vertical direction in its longitudinal direction. The first hollow shaft 540 is provided with the same diameter in its longitudinal direction. A flange 542 is provided on the upper end of the first hollow shaft 540. The flange 542 has the same diameter as the first inner plate 560. The first inner plate 560 is fixedly coupled to the flange 542. A passage with an empty space is formed inside the first hollow shaft 540. A cleaning liquid and a treatment liquid are discharged through the inner space of the first hollow shaft 540.

The first driver 580 rotates the first hollow shaft 540 with respect to a rotation axis C. By the rotation of the first hollow shaft 540, the first inner plate 560 is also rotated together with the first hollow shaft 540. The first driver 580 adjusts a rotation direction, a rotation speed, and a rotation period, and the like of the first inner plate 560. The first driver 580 is controlled by a controller 2. According to an exemplary embodiment, the first driver 580 includes a belt 582 and a motor 584. A part of the belt 582 is engaged with an outer surface of the first hollow shaft 540, and the other part of the belt 582 is engaged with a shaft of the motor 584.

The longitudinal direction of the second hollow shaft 550 is provided in the vertical direction. The second hollow shaft 550 is provided with the same diameter in its longitudinal direction. A flange 552 is provided on an upper end of the second hollow shaft 550. The flange 552 has the same diameter as the second inner plate 570. The second inner plate 570 is spaced apart from the flange 552 of the second hollow shaft 550 by the height of the first inner plate 560. The flange 552 of the second hollow shaft 550 and the second inner plate 570 are fixedly coupled by a plurality of slender rod-shaped support body 556. For example, three support bodies 556 may be provided. The support bodies 556 may be disposed to be spaced apart from each other by the same interval. The first hollow shaft 540 is disposed inside the second hollow shaft 550.

The second driver 590 rotates the second hollow shaft 550 with respect to the rotation axis C. By rotation of the second hollow shaft 550, the second inner plate 570 is also rotated together with the second hollow shaft 550. The second driver 590 adjusts a rotation direction, a rotation speed, a rotation period, and the like of the second inner plate 570. The second driver 590 is controlled by the controller 2. According to an exemplary embodiment, the second driver 590 has a belt 592 and a motor 594. A part of the belt 592 is engaged with an outer surface of the second hollow shaft 550, and the other part of the belt 592 is engaged with a shaft of the motor 594.

A liquid valve 602 and a first depressurization member 604 are installed in the cleaning liquid supply pipe 600. The liquid valve 602 may include an opening/closing valve and/or a flow rate control valve. The first depressurization member 604 depressurizes the inside of the cleaning liquid supply pipe 600 so as to suck gas in the first space 531 to the cleaning liquid supply pipe 600. The first depressurization member 604 may be a pump or an ejector. The cleaning liquid supply pipe 600 connects the cleaning liquid supply source 606 to the first buffer space 532. The cleaning liquid supply pipe 600 supplies the cleaning liquid from the cleaning liquid supply source 606 to the first buffer space 532. In one exemplary embodiment, the cleaning liquid may be pure water.

A gas valve 612 is installed in the second gas supply pipe 610. The gas valve 612 may include an opening/closing valve and/or a gas pressure control valve. The second gas supply pipe 610 connects the gas supply source 616 to the second buffer space 536. The second gas supply pipe 610 supplies gas from the gas supply source 616 to the second buffer space 536. In an exemplary embodiment, the gas may be air. Optionally, the gas may be inert gas, such as nitrogen (N₂).

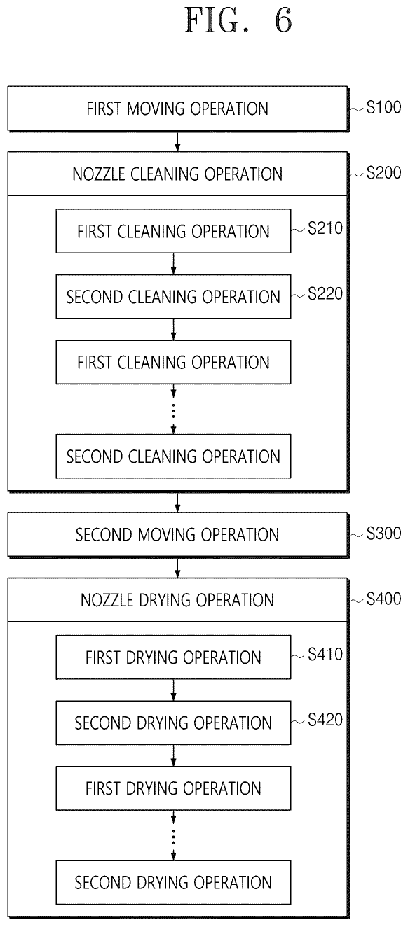

Hereinafter, a process of cleaning the nozzle in the cleaning unit of FIG. 5 will be described in detail with reference to FIGS. 6 to 10.

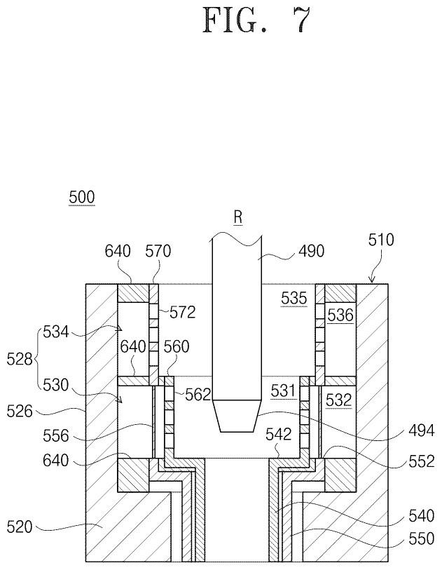

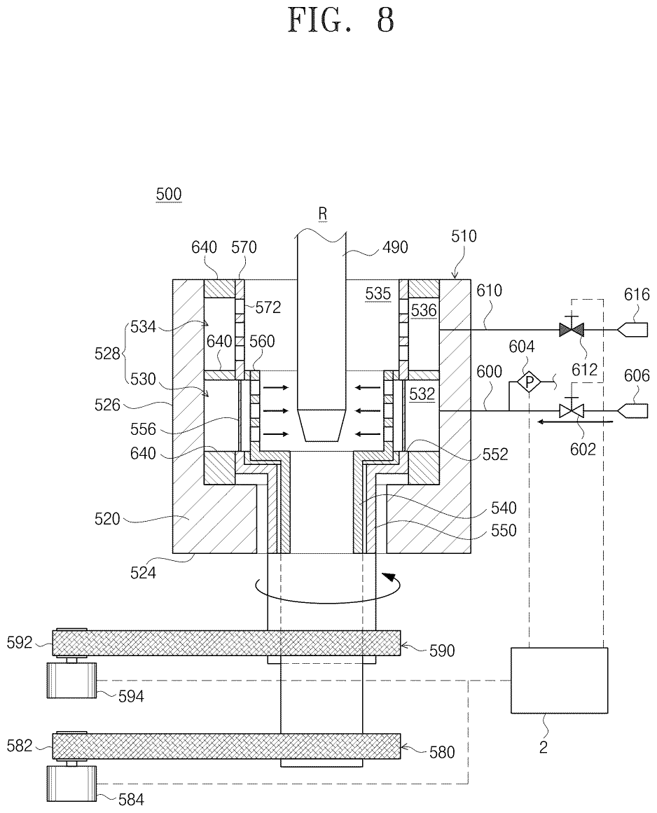

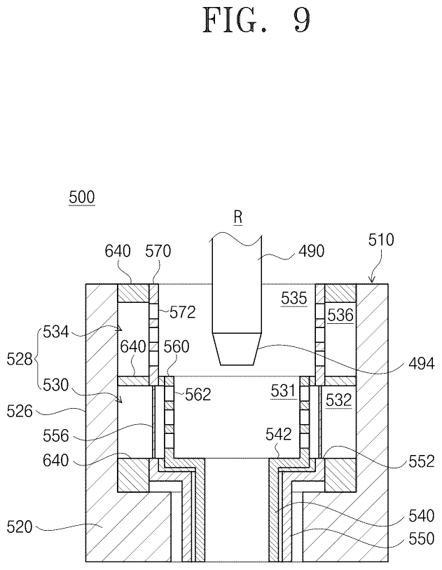

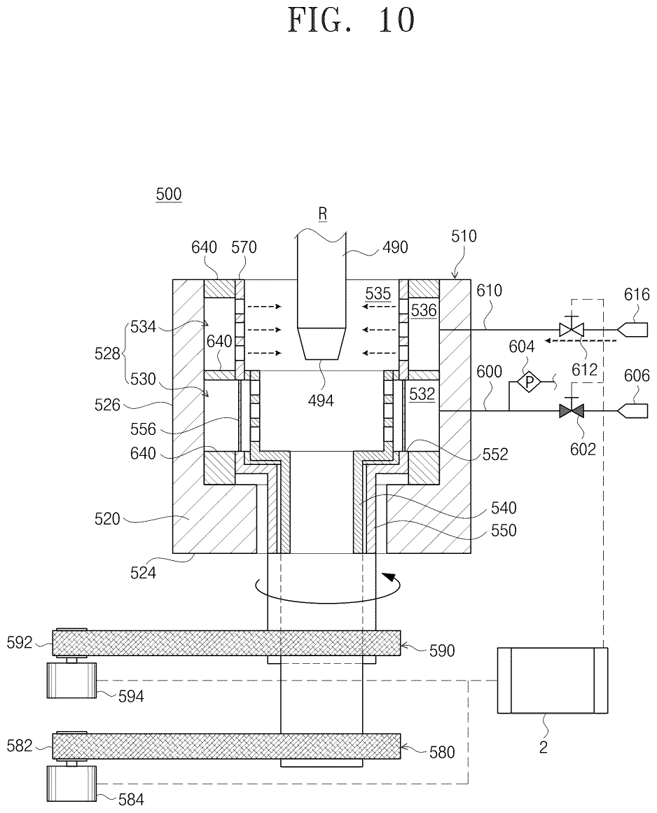

FIG. 6 is a flowchart schematically illustrating a nozzle cleaning method according to an exemplary embodiment of the present invention. FIG. 7 is a cross-sectional view schematically illustrating a position of a nozzle in a first moving operation of FIG. 6. FIG. 8 is a cross-sectional view schematically illustrating the cleaning unit in a nozzle cleaning operation of FIG. 6. FIG. 9 is a cross-sectional view schematically illustrating a position of a nozzle in a second moving operation of FIG. 6. FIG. 10 is a cross-sectional view schematically illustrating the cleaning unit in a nozzle drying operation of FIG. 6.

In FIGS. 8 and 10, a solid line arrow indicates a flow path of the cleaning liquid, and a dotted arrow indicates a flow of gas. In addition, in FIGS. 8 and 10, a valve filled with the inside represents a closed state, and a valve empty with the inside represents an open state.

Referring to FIG. 6, the nozzle cleaning process has a first moving operation S100, a nozzle cleaning operation S200, a second moving operation S300, and a nozzle drying operation 400.

The first moving operation S100, the nozzle cleaning operation S200, the second moving operation S300, and the nozzle drying operation S400 are sequentially performed. The nozzle cleaning operation S200 includes a first cleaning operation S210 and a second cleaning operation S220. The nozzle drying operation S400 includes a first drying operation S410 and a second drying operation S420.

Referring to FIG. 7, in the first moving operation S100, the nozzles 490 located at the standby position R are inserted into the first space 531 by the nozzle driver 468. In the first moving operation S100, the nozzle tip 494 is located in the first space 531. The nozzles 490 are arranged in a line in the first space 531.

Next, the nozzle cleaning operation S200 is performed.

In the nozzle cleaning operation S200, as illustrated in FIG. 8, the liquid valve 602 is opened and the gas valve 612 is closed. Accordingly, the cleaning liquid is supplied to the first space 531 through the first buffer space 532. The cleaning liquid filled in the first buffer space 532 is injected into the first space 531 through the through hole 562 formed in the first inner plate 560.

In the nozzle cleaning operation S200, the first cleaning operation S210 is first performed. In the first cleaning operation S210, the first inner plate 560 is rotated in the first direction by the first driver 580. After the first cleaning operation S210 is performed, the second cleaning operation S220 is performed. In the second cleaning operation S220, the first inner plate 560 is rotated in the second direction opposite to the first direction by the first driver 580. In the nozzle cleaning operation S200, the first cleaning operation S210 and the second cleaning operation S220 are repeatedly performed a plurality of times.

An acid component chemical or an alkali component chemical is used as a treatment liquid for liquid-treating the substrate W. When these chemicals are discharged toward the cleaning unit 500, a part of the treatment liquid remains on the nozzle tip 494. As the treatment liquid having different properties is discharged after the remaining treatment liquid, contaminants, such as salt compound, are generated in the nozzle tip 494. For example, when a chemical of an acid component, such as sulfuric acid, is discharged as the first treatment liquid, a part of the first treatment liquid remains on the nozzle tip 494, and then when a chemical of an alkali component, such as ammonia, is discharged as the second treatment liquid, a salt compound is generated in the nozzle tip 494. Particles, such as salt compounds, remain on the nozzle tip 494 and are injected together onto the substrate W when the treatment liquid is discharged, thereby adversely affecting process efficiency. In addition, in the past, there was a problem that it took a lot of time, such as having to periodically wipe the nozzle tip 494 manually to remove contaminants.

The first inner plate 560 may be variously controlled according to characteristics of the treatment liquid to remove particles remaining on the nozzle tip 494.

In the first cleaning operation S210 and the second cleaning operation S220, the rotation angle of the first inner plate 560 may be set differently according to the degree of adhesion of contaminants generated by remaining on the nozzle tip 494. For example, in the case where the treatment liquid used for the treatment of the substrate W is a treatment liquid having a property of easily attached to the nozzle tip 494, it may be inferred that a large amount of contaminants will be attached to the nozzle tip 494 after the treatment liquid is discharged. After rotating the first inner plate 560 by increasing the rotation angle of the first inner plate 560 in the first cleaning operation S210, the first inner plate 560 may be rotated in the opposite direction in the second cleaning operation S220. Also, the rotation angle in the first cleaning operation S210 and the rotation angle in the second cleaning operation S220 may be set differently.

According to an exemplary embodiment, a camera (not illustrated) may be installed in the cleaning unit 500. Accordingly, the nozzle tip 494 may be photographed to determine the degree of adhesion of contaminants attached to the nozzle tip 494, and thus the number of rotations of the first inner plate 560 and the like may be adjusted.

When a treatment liquid having the property that a large amount of contaminants attached to the nozzle tip 494 is used, the number of rotations of the first inner plate 560 may be increased. For example, when a treatment liquid with a low degree of adhesion of contaminants is used, the first inner plate 560 may be rotated n times at an angle of 360 degrees in the first direction or the second direction, and when a treatment liquid with a high degree of adhesion of contaminants is used, the first inner plate may be rotated m times (m is a natural number greater than n) at an angle of 360 degrees in the first direction or the second direction.

Variables, such as the rotation angle and the number of rotations, are exemplary and may be variously set according to the degree to which contaminants are attached to the nozzle tip 494. For example, the rotation speed and the rotation angle may be adjusted together, or the rotation speed and the number of rotations may be adjusted together. Alternatively, it is also possible to control the flow rate of the supplied cleaning liquid together. Through these various control methods, even when the plurality of nozzles 490 is inserted, cleaning efficiency for each nozzle 490 may be improved without blind spots.

In the nozzle cleaning operation S200, as the first inner plate 560 repeatedly rotates in the first direction and the second direction, the direction of the cleaning liquid injected through the through hole 562 of the first inner plate 560 is irregularly changed. The direction of the injected cleaning liquid is irregularly changed so that the cleaning liquid may evenly reach the surface of the nozzle tip 494. Accordingly, the cleaning liquid also reaches a region between the nozzle and the nozzle, and residues on the nozzle tip 494 may be effectively removed.

When the nozzle cleaning operation S200 is completed, the second moving operation S300 is performed.

Referring to FIG. 9, in the second moving operation S300, the nozzles 490 move up and down to the second space 535 by the nozzle driver 468. In an exemplary embodiment, in the second moving operation S300, the nozzles 490 move upward. In the second moving operation S300, the nozzle tip 494 is located in the second space 535.

Next, the nozzle drying operation S400 is performed.

In the nozzle drying operation S400, the gas valve 612 is opened and the liquid valve 602 is closed as illustrated in FIG. 10. Accordingly, the gas is supplied to the second space 535 through the second buffer space 536. The gas filled in the second buffer space 536 is injected to the second space 535 through the through hole 572 formed in the second inner plate 570.

Also, in the nozzle drying operation S400, the inside of the cleaning liquid supply pipe 600 may be depressurized by the first depressurization member 604. Accordingly, the gas supplied through the second gas supply pipe 610 may be exhausted through the cleaning liquid supply pipe 600. Accordingly, the flow of the gas is maintained smoothly, thereby increasing the consistency of the cleaning process and increasing the cleaning efficiency.

In the nozzle drying operation S400, the first drying operation S410 is performed first. In the first drying operation S410, the second inner plate 570 is rotated in the first direction by the second driver 590. Thereafter, the second drying operation S420 is performed. In the second drying operation S420, the second inner plate 570 is rotated in the second direction by the second driver 590. The second inner plate 570 may be driven in the same manner as the first inner plate 560 described above. In the nozzle drying operation S400, the first drying operation S410 and the second drying operation S420 are repeatedly performed a plurality of times.

In the nozzle drying operation S400, as the second inner plate 570 is repeatedly rotated in the first direction and the second direction, the direction of the gas injected through the through hole 572 of the second inner plate 570 is irregularly changed. The direction of the injected gas is irregularly changed so that the gas may evenly reach the surface of the nozzle tip 494. Accordingly, the gas also reaches a region between the nozzle and the nozzle, and thus the residual cleaning liquid on the nozzle tip 494 may be effectively dried.

In the above-described exemplary embodiment, it has been described that the two inner plates 560 and 570 are provided in the cleaning unit 500. However, the present invention is not limited thereto, and only one inner plate 560 may be provided in the cleaning unit 500. Hereinafter, the cleaning unit 500 in which one inner plate 560 is provided will be described focusing on differences from the above-described exemplary embodiment.

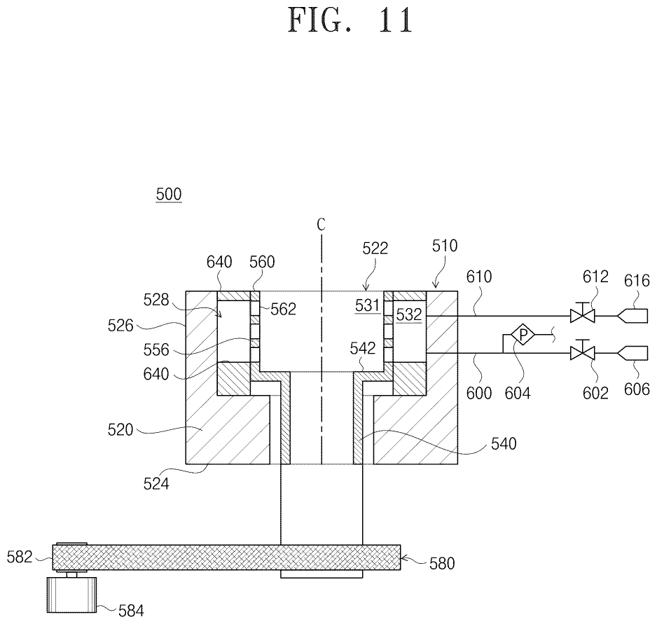

Referring to FIG. 11, the cleaning unit 500 may include a body 510, a first inner plate 560, a first driver 580, a cleaning liquid supply pipe 600, a first gas supply pipe 610, and a liquid discharge pipe 620.

The body 510 includes an outer wall 520 and a first hollow shaft 540. The inner space 528 formed inside the outer wall 520 includes a first space 531 and a first buffer space 532. The outer wall 520 is provided in a cylindrical shape with an open upper portion 522 and an empty inside. The outer wall 520 is provided in a ring shape when viewed from the top. A bottom surface 524 of the outer wall 520 is provided as a flat surface.

The first inner plate 560 is provided in the inner space 528. The first inner plate 560 divides the inner space into a first space 531 and a first buffer space 532. In the first space 531, the nozzle 490 is cleaned and dried with a cleaning liquid. The first buffer space 532 is located outside the first space 531. The first buffer space 532 is formed in a ring shape to surround the first space 531. A separation wall 640 separating the first buffer space 532 from the outside is provided at upper and lower portions of the first buffer space 532. A bearing may be installed at a point where the separation wall 640 is in contact with the first inner plate.

A plurality of through holes 562 is formed in the first inner plate 560. A plurality of through holes 562 is formed to form a plurality of rows in a direction along the circumference of the side surface 526 of the outer wall 520. For example, a plurality of through holes 562 may be formed to form three rows in the first inner plate 560. A plurality of through holes 562 is formed in a horizontal direction with respect to the ground.

A liquid valve 602 and a first depressurization member 604 are installed in the cleaning liquid supply pipe 600. A gas valve 612 is installed in the first gas supply pipe 610. The first gas supply pipe 610 connects the gas supply source 616 to the second buffer space 532. The first gas supply pipe 610 supplies gas from the gas supply source 616 to the first buffer space 532.

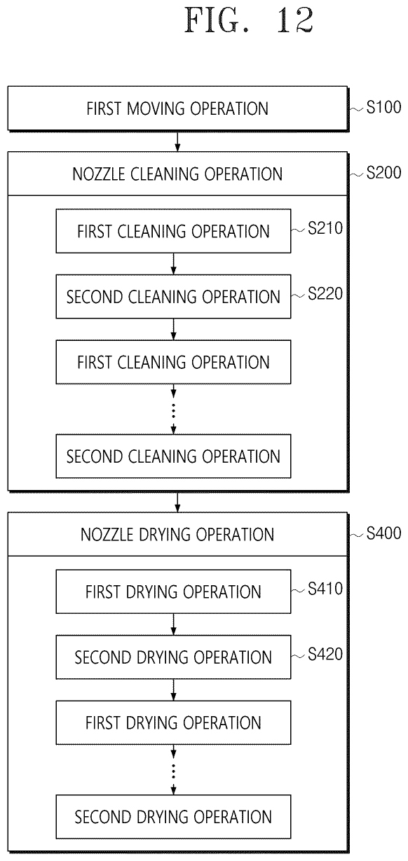

FIG. 12 is a flowchart schematically illustrating a nozzle cleaning method according to FIG. 11.

Referring to FIG. 12, the nozzle cleaning process has a first moving operation S100, a nozzle cleaning operation S200, and a nozzle drying operation 400.

The first moving operation S100, the nozzle cleaning operation S200, and the nozzle drying operation S400 are sequentially performed. The nozzle cleaning operation S200 includes a first cleaning operation S210 and a second cleaning operation S220, and details of the first cleaning operation S210 and the second cleaning operation S220 are the same as in the previous exemplary embodiment.

When the nozzle cleaning operation S200 is completed, the nozzle drying operation S400 is performed immediately. In the nozzle drying operation S400, the nozzles 490 are still located in the first space 531.

The fact that the nozzle drying operation S400 includes the first drying operation S410 and the second drying operation S420, and details of the first cleaning operation S410 and the second cleaning operation S420 are the same as in the previous exemplary embodiment.

Also, in the nozzle drying operation S400, the inside of the cleaning liquid supply pipe 600 may be depressurized by the first depressurization member 604. Accordingly, the gas supplied through the first gas supply pipe 610 may be exhausted through the cleaning liquid supply pipe 600.

In the first drying operation S410, the first inner plate 560 is rotated in the first direction by the first driver 580. Thereafter, the second drying operation S420 is performed. In the second drying operation S420, the first inner plate 560 is rotated in the second direction by the first driver 580. In the nozzle drying operation S400, the first drying operation S410 and the second drying operation S420 are repeatedly performed a plurality of times. In the first drying operation S410 and the second drying operation S420, the second inner plate 570 may be controlled in the same manner as controlling the rotation speed, rotation angle, and number of rotations of the first inner plate 560 described above. Accordingly, drying efficiency of the cleaning liquid remaining on the nozzle tip 494 may be improved.

Hereinafter, various modified examples of the cleaning unit and the nozzle cleaning method according to the present invention will be described.

In the above exemplary embodiment, it has been described that the plurality of nozzles 490 is simultaneously inserted into the cleaning unit 500. However, the present invention is not limited thereto. Only one nozzle 490 may be inserted into the cleaning unit 500 to be cleaned and dried. Also, there may be a case where each nozzle 490 is individually inserted into the cleaning unit 500 by the nozzle driver 468.

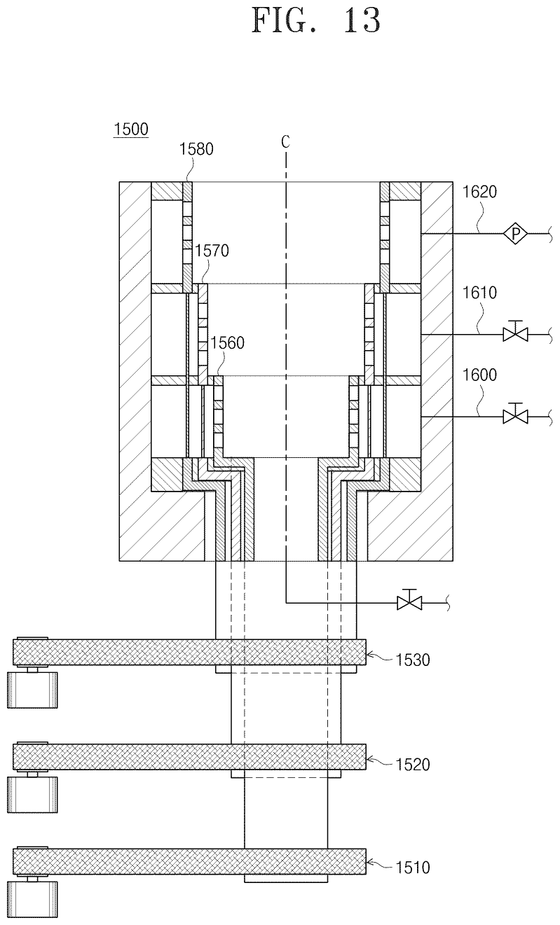

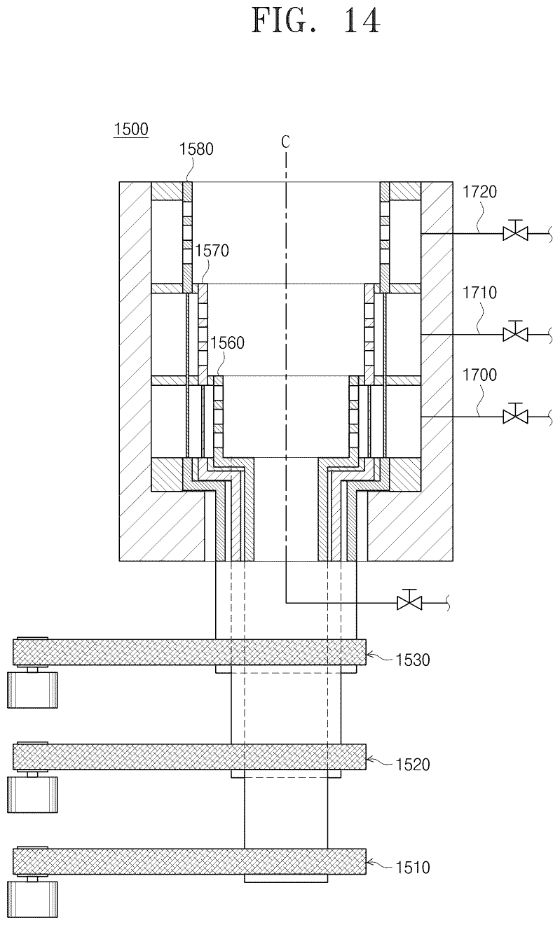

In the above exemplary embodiment, it has been described that one or two inner plates 560 and 570 are provided in the cleaning unit 500. However, the present invention is not limited thereto. Three or more inner plates may be provided in the cleaning unit 1500. Referring to FIG. 13, a cleaning treatment may be performed through the inner plate 1560 located at the lowest height, a drying treatment may be performed through the inner plate 1570 located at the intermediate height, and an intake treatment may be performed on the inner plate 1580 located at the highest height. In this case, the cleaning liquid supply pipe 1600, the gas supply pipe 1610, and the exhaust pipe 1620 may be connected at different heights, and the drivers 1510, 1520, and 1530 for rotating the three inner plates 1560, 1570, and 1580, respectively, may be provided. Alternatively, as illustrated in FIG. 14, a cleaning treatment may be performed through the two inner plates 1560 and 1570 located at a low height, and a drying treatment may be performed through the inner plate 1580 located at the highest height, and the cleaning liquid may be supplied at different types and temperatures of the cleaning liquid. In this case, the cleaning liquid supply pipes 1700 and 1710 are connected to the lowest height and the intermediate height, and the gas supply pipe 1720 is connected to the highest height. The first cleaning liquid may be supplied through the inner plate 1560 located at the lowest height, and the second cleaning liquid having a component different from the first cleaning liquid may be supplied through the inner plate 1570 located at the intermediate height. Alternatively, the cleaning liquid may be supplied at a first temperature through the inner plate 1560 located at the lowest height, and the cleaning liquid may be supplied at a second temperature through the inner plate 1570 located at the intermediate height.

In the above-described exemplary embodiment, the first space 531 in which the cleaning treatment is performed is formed at a lower height than the second space 535 in which the drying treatment is performed. However, the present invention is not limited thereto, and the first space 531 may also be formed at a higher position than the second space 535.

In the above-described exemplary embodiment, it has been described that the plurality of through holes 562 and 572 formed in the first inner plate 560 and the second inner plate 570 is formed in a horizontal direction with respect to the ground. However, the present invention is not limited thereto. Among the plurality of through holes 562 formed in the first inner plate 560, the through holes forming the uppermost row may be provided to be inclined downward in the direction from the first buffer space 532 toward the first space 531. Similarly, among the plurality of through holes 572 formed in the second inner plate 570, the through holes forming the uppermost row may be provided to be inclined downward in the direction from the second buffer space 536 toward the second space 535.

In the above-described exemplary embodiment, it has been described that the rotation angle and the number of rotations of the first inner plate 560 and/or the second inner plate 570 are varied according to the degree of adhesion of contaminants remaining on the nozzle tip 494. Alternatively, the rotation speed of the first inner plate 560 and/or the second inner plate 570 may be varied according to the amount of contaminants attached to the nozzle tip 494.

In the above-described exemplary embodiment, it has been described that the rotation angle and the number of rotations of the first inner plate 560 and/or the second inner plate 570 are varied according to the degree of adhesion of contaminants remaining on the nozzle tip 494. Alternatively, the flow rate of the cleaning liquid may be differently supplied according to the amount of contaminants attached to the nozzle tip 494. According to the exemplary embodiment, when a large amount of contaminants is attached to the nozzle tip 494 from the treatment liquid remaining on the nozzle tip 494, the flow rate of the supplied cleaning liquid may be increased to effectively remove the contaminants.

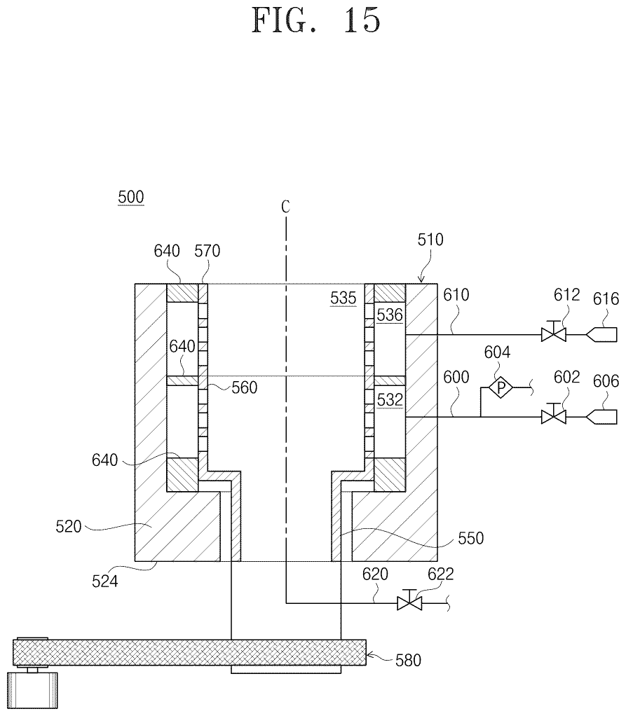

In the above exemplary embodiment, it has been described that the first inner plate 560 and the second inner plate 570 are rotated independently of each other by the first driver 580 and the second driver 590. However, this is illustrative and the present invention is not limited thereto. Referring to FIG. 15, the inner plate may be provided as one inner plate 560. In this case, the inner plate 560 is rotated by one driver 580.

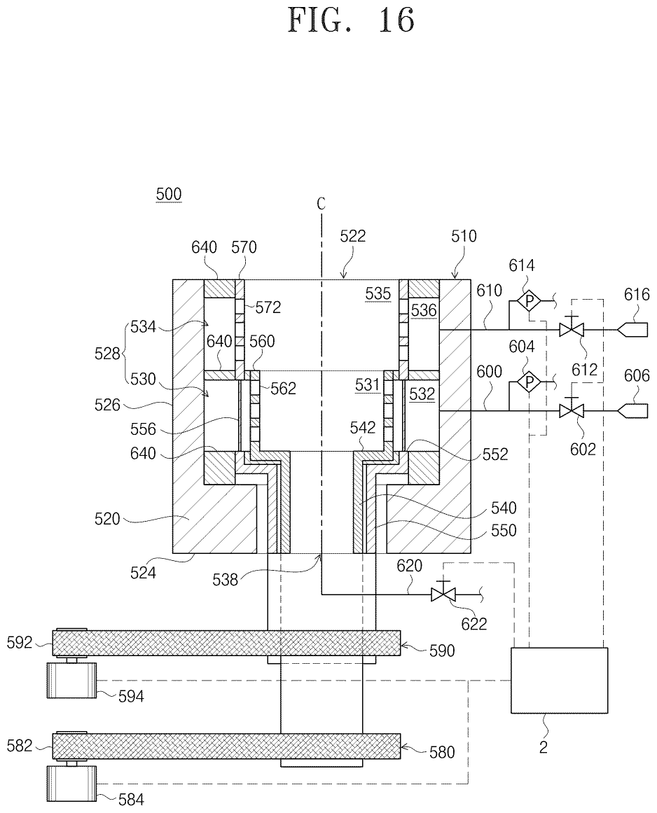

In the above exemplary embodiment, it has been described that the first depressurization member 604 is installed in the cleaning liquid supply pipe 600. However, this is illustrative and the present invention is not limited thereto. As illustrated in FIG. 16, the second depressurization member 614 may also be installed in the second gas supply pipe 610. The second depressurization member 614 depressurizes the inside of the second gas supply pipe 610 to suck gas in the second space 535 to the second gas supply pipe 610. The second depressurization member 614 may be a pump or an ejector. The internal gas may be exhausted through the second gas supply pipe 610 even in the nozzle cleaning operation S200 by the second depressurization member 614 installed in the second gas supply pipe 610. Accordingly, even when the high-pressure cleaning liquid is injected in the nozzle cleaning operation S200, the flow of the cleaning liquid may be maintained smoothly, and the cleaning treatment may be performed through the high-pressure cleaning liquid.

In the above exemplary embodiment, it has been described that the cleaning liquid supply pipe 600 and the second gas supply pipe 610 are connected at different heights. However, this is illustrative and the present invention is not limited thereto. The cleaning liquid supply pipe 600 and the first gas supply pipe 1610 may be connected to the first buffer space 532, and the cleaning liquid supply pipe 600 and the second gas supply pipe 610 may be connected to the second buffer space 535. Also, in this case, the nozzles 490 may be inserted into the inner space 528 together and positioned at different heights, respectively. In the nozzle cleaning operation S200, the cleaning liquid may be supplied to the first buffer space 532 and the second buffer space 536, and in the nozzle drying operation S400, gas may be supplied to the first buffer space 532 and/or the second buffer space 536.

In the above-described exemplary embodiment, it has been described that the cleaning liquid is pure water. However, the present invention is not limited thereto, and isopropyl alcohol (IPA) other than pure water may be used.

In the above exemplary embodiment, it has been described that the first driver 580 and the second driver 590 are provided in a belt manner. However, this is illustrative and the present invention is not limited thereto. The first driver 580 and the second driver 590 may be provided as other driving devices for rotating the first inner plate 560 and the second inner plate 570.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

What is claimed is:

1. An apparatus for processing a substrate, the apparatus comprising:
a cup unit having a treatment space for liquid-treating a substrate with a treatment liquid;
a support unit for supporting the substrate within the treatment space;
a nozzle unit including a nozzle that supplies a treatment liquid to the substrate supported by the support unit; and
a cleaning unit located on one side of the cup unit and cleaning the nozzle,
wherein the cleaning unit includes:
a body having an inner space;
a first inner plate for dividing the inner space into a first space where the nozzle is located and a first buffer space outside the first space;
a cleaning liquid supply pipe with a liquid valve installed and supplying a cleaning liquid for cleaning the nozzle located in the first space into the first buffer space;
a first driver for rotating the first inner plate about a central axis thereof;
a second inner plate for dividing the inner space into a second space at a height different from the first space and a second buffer space outside the second space;
a second gas supply pipe with a second gas valve installed and supplying gas for drying the nozzle located in the second space into the second buffer space; and
a second driver for rotating the second inner plate about a central axis thereof.

2. The apparatus of claim 1, wherein a plurality of through holes are formed in the first inner plate to allow a fluid to flow between the first buffer space and the first space.

3. The apparatus of claim 1, wherein the nozzle unit further includes:
a support frame;
a plurality of arms supported side by side on the support frame in one direction and equipped with the nozzles at ends, respectively; and
a nozzle driver for driving the support frame so that the nozzle is moved between a standby position and a process position,
the nozzle installed in the plurality of arms is inserted into the inner space from the standby position by the nozzle driver,
the apparatus further comprises a controller for controlling the first driver, the liquid valve, and the nozzle driver, and
the controller controls the first driver, the liquid valve, and the nozzle driver to perform a first cleaning operation of cleaning the nozzle with a cleaning liquid supplied through the first buffer space by opening the liquid valve while rotating the first inner plate after the nozzle located in the standby position is inserted into the first space.

4. The apparatus of claim 3, wherein in the first cleaning operation, the first inner plate is rotated in a first direction, and
the controller controls the first driver to perform a second cleaning operation of cleaning the nozzle with the cleaning liquid supplied through the first buffer space while rotating the first inner plate in a second direction opposite to the first direction, after the first cleaning operation.

5. The apparatus of claim 4, wherein the nozzle unit further includes:
a support frame;
a plurality of arms supported side by side on the support frame in one direction, with the nozzles respectively installed at their ends; and
a nozzle driver for driving the support frame so that the nozzle is moved between the first space and the second space,
the nozzles installed in the plurality of arms are simultaneously inserted from the first space to the second space,
the controller further controls the second driver, the second gas valve, and the nozzle driver, and
the controller controls the second driver, the second gas valve, and the nozzle driver to perform a first drying operation of drying the nozzle with gas supplied through the second buffer space by closing the liquid valve and opening the second gas valve while rotating the second inner plate after the nozzle located in the first space is inserted into the second space.

6. The apparatus of claim 5, wherein in the first drying operation, the second inner plate rotates in the first direction, and
the controller controls the second driver to perform a second drying operation of drying the nozzle with the gas supplied through the second buffer space while rotating the second inner plate in a second direction opposite to the first direction after the first drying operation, and the first drying operation and the second drying operation are repeatedly performed several times.

7. The apparatus of claim 1, wherein the cleaning unit further includes a first gas supply pipe in which a first gas valve is installed and which supplies gas for drying the nozzle located in the first space into the first buffer space, and
a second depressurization member for exhausting the gas in the inner space to the outside is further installed in the second gas supply pipe.

8. The apparatus of claim 7, wherein the nozzle unit further includes:
a support frame;
a plurality of arms supported side by side on the support frame in one direction, with the nozzles respectively installed at their ends; and
a nozzle driver for driving the support frame so that the nozzle is moved between a standby position and a process position,
the apparatus further includes a controller for controlling the first driver, the second driver, the liquid valve, the first gas valve, the first depressurization member, and the nozzle driver, and
the controller controls the first driver, the liquid valve, the first gas valve, the first depressurization member, and the nozzle driver to perform: a first cleaning operation of cleaning the nozzle with a cleaning liquid supplied through the first buffer space by opening the liquid valve while rotating the first inner plate after the nozzle located in the standby position is inserted into the first space; a first drying operation of drying the nozzle with the gas supplied through the first buffer space by opening the first gas valve while rotating the first inner plate after the first cleaning operation is performed; and an exhaust operation of exhausting the gas in the inner space to the outside through the second depressurization member while the first drying operation is performed.

9. The apparatus of claim 1, wherein the cleaning unit further includes:
a third inner plate for dividing the inner space into a third space where the nozzle is located and a third buffer space outside the third space;
a second cleaning liquid supply pipe with a second liquid valve installed and supplying a cleaning liquid to clean the nozzle located in the third space into the third buffer space; and
a third driver for rotating the third inner plate about a central axis thereof.

10. The apparatus of claim 1, wherein the cleaning unit further includes a second gas supply pipe in which a second gas valve is installed and which supplies gas for drying the nozzle located in the second space into the second buffer space, and
a first depressurization member for exhausting the gas in the inner space to the outside is further installed in the first gas supply pipe.

11. The apparatus of claim 10, wherein the nozzle unit further includes:
a support frame;
a plurality of arms supported side by side on the support frame in one direction, with the nozzles respectively installed at their ends; and
a nozzle driver for driving the support frame so that the nozzle is moved between a standby position and a process position,
the apparatus further includes a controller for controlling the first driver, the second driver, the liquid valve, the second gas valve, the first depressurization member, and the nozzle driver, and
the controller controls the second driver, the liquid valve, the second gas valve, the first depressurization member, and the nozzle driver to perform: a second drying operation of drying the nozzle with gas supplied through the second buffer space by closing the liquid valve and opening the second gas valve while rotating the second inner plate, after the nozzle located in the first space is inserted into the second space; and a first exhaust operation of exhausting the gas in the inner space to the outside through the first depressurization member while the second drying operation is performed.

12. The apparatus of claim 1, further comprising:
a controller for controlling the first driver,
wherein the controller controls the first driver to increase the number of rotations of the first inner plate as more contaminants generated due to the treatment liquid used for substrate processing remaining on a nozzle tip are attached.

13. The apparatus of claim 12, wherein the contaminant is a salt compound.

14. An apparatus for processing a substrate, the apparatus comprising:
a cup unit having a treatment space for liquid-treating a substrate with a treatment liquid;
a support unit for supporting the substrate within the treatment space;
a nozzle unit including a nozzle that supplies a treatment liquid to the substrate supported by the support unit; and
a cleaning unit located on one side of the cup unit and cleaning the nozzle,
wherein the cleaning unit includes:
a body having an inner space;
a first inner plate for dividing the inner space into a first space where the nozzle is located and a first buffer space outside the first space;
a cleaning liquid supply pipe with a liquid valve installed and supplying a cleaning liquid for cleaning the nozzle located in the first space into the first buffer space;
a first gas supply pipe with a first gas valve installed and supplying gas for drying the nozzle located in the first space into the first buffer space; and
a first driver for rotating the first inner plate about a central axis thereof, and
a plurality of through holes are formed in the first inner plate to allow a fluid to flow between the first buffer space and the first space.

15. The apparatus of claim 14, wherein the nozzle unit further includes:
a support frame;
a plurality of arms supported side by side on the support frame in one direction, with the nozzles respectively installed at their ends; and
a nozzle driver for driving the support frame so that the nozzle is moved between a standby position and a process position, and
the nozzle installed in the plurality of arms is inserted into the inner space from the standby position by the nozzle driver,
the apparatus further includes a controller for controlling the first driver, the liquid valve, the first gas valve, and the nozzle driver, and
the controller controls the first driver, the liquid valve, and the nozzle driver to perform a first cleaning operation of cleaning the nozzle with a cleaning liquid supplied through the first buffer space by opening the liquid valve while rotating the first inner plate after the nozzle located in the standby position is inserted into the first space.

16. The apparatus of claim 15, wherein in the first cleaning operation, the first inner plate is rotated in a first direction, and
the controller controls the first driver to perform a second cleaning operation of cleaning the nozzle with the cleaning liquid supplied through the first buffer space while rotating the first inner plate in a second direction opposite to the first direction, after the first cleaning operation.

17. The apparatus of claim 16, wherein a first depressurization member for exhausting the gas in the inner space to the outside is further installed in the cleaning liquid supply pipe,
the apparatus further includes a controller for controlling the first driver, the liquid valve, the first gas valve, the first depressurization member, and the nozzle driver, and
the controller controls the first driver, the liquid valve, the first gas valve, and the first depressurization member to perform an exhaust operation of exhausting the gas in the inner space to the outside through the first depressurization member while a first drying operation of drying the nozzle with gas supplied through the first buffer space is performed by closing the liquid valve and opening the first gas valve while rotating the first inner plate, after the first cleaning operation is performed.

18. The apparatus of claim 14, further comprising:
a controller for controlling the first driver,
wherein the controller controls the first driver to increase the number of rotations of the first inner plate as more contaminants generated due to the treatment liquid used for substrate processing remaining on a nozzle tip are attached.

19. The apparatus of claim 18, wherein the contaminant is a salt compound.

20. An apparatus for processing a substrate, the apparatus comprising:
a cup unit having a treatment space for liquid-treating a substrate with a treatment liquid;
a support unit for supporting the substrate within the treatment space;
a nozzle unit including a nozzle that supplies a treatment liquid to the substrate supported by the support unit; and
a cleaning unit located on one side of the cup unit and cleaning the nozzle,
wherein the cleaning unit includes:
a support frame;
a plurality of arms supported side by side on the support frame in one direction, with the nozzles respectively installed at their ends;
a nozzle driver for driving the support frame so that the nozzle is moved between a standby position and a process position;
a body having an inner space;
a first inner plate for dividing the inner space into a first space where the nozzle is located and a first buffer space outside the first space;
a cleaning liquid supply pipe with a liquid valve installed and supplying a cleaning liquid for cleaning the nozzle located in the first space into the first buffer space;
a first driver for rotating the first inner plate about a central axis thereof;
a second inner plate for dividing the inner space into a second space at a height different from the first space and a second buffer space outside the second space;
a second gas supply pipe with a second gas valve installed and supplying gas for drying the nozzle located in the second space into the second buffer space; and
a second driver for rotating the second inner plate about a central axis thereof, and
a plurality of through holes are formed in the first inner plate to allow a fluid to flow between the first buffer space and the first space,
a plurality of through holes are formed in the second inner plate to allow a fluid to flow between the second buffer space and the second space,
the nozzle installed in the plurality of arms is inserted into the inner space from the standby position by the nozzle driver,
the apparatus further includes a controller for controlling the first driver, the liquid valve, the second gas valve, and the nozzle driver, and
the controller controls the first driver, the second driver, the liquid valve, the second gas valve, and the nozzle driver to perform: a first cleaning operation of cleaning the nozzle with a cleaning liquid supplied through the first buffer space by opening the liquid valve while rotating the first inner plate in a first direction, after the nozzle located in the standby position is inserted into the first space; a second cleaning operation of cleaning the nozzle with the cleaning liquid supplied through the first buffer space while rotating the first inner plate in a second direction opposite to the first direction, after the first cleaning operation; and a second drying operation of drying the nozzle with gas supplied through the second buffer space by closing the liquid valve and opening the second gas valve while rotating the second inner plate, after the nozzle located in the first space is inserted into the second space.
